(19) United States
(12) Patent Application Publication
(10) Pub. No.: US 2014/0301025 A1
(43) Pub. Date: Oct. 9, 2014

(54) ANTI-VIBRATION FIXING STRUCTURE AND ELECTRONIC DEVICE USING THE SAME

(71) Applicant: ASUSTeK Computer Inc., Taipei (TW)

(72) Inventor: Yu-Ming LIU, Taipei (TW)

(73) Assignee: ASUSTeK Computer Inc., Taipei (TW)

(21) Appl. No.: 14/229,228

(22) Filed: Mar. 28, 2014

Related U.S. Application Data
(60) Provisional application No. 61/807,963, filed on Apr. 3, 2013.

(30) Foreign Application Priority Data
Nov. 12, 2013 (TW) 102141142

(51) Int. Cl. F16F 15/04; H05K 7/02

(52) U.S. Cl. CPC F16F 15/04; H05K 7/02
USPC 361/679.01; 248/560

(57) ABSTRACT

An electronic device includes an electronic component, a fixing plate, an anti-vibration fixing structure and a locking element. The fixing plate fixes the electronic component. The anti-vibration fixing structure is disposed at the fixing plate and includes a connecting portion and a buffer. The connecting portion has a hole. The buffer is connected to the connecting portion and the fixing plate. The locking member gets through the hole and locks the electronic component on the fixing plate.

### CROSS-REFERENCE TO RELATED APPLICATION

This application claims the priority benefits of U.S. provisional application Ser. No. 61/807,963, filed on Apr. 3, 2013 and Taiwan application serial No. 102141142, filed on Nov. 12, 2013. The entirety of the above-mentioned patent applications are hereby incorporated by references herein and made a part of specification.

### BACKGROUND OF THE INVENTION

1. Field of the Invention

The disclosure relates to an electronic device and, more particularly, to an electronic device including an anti-vibration fixing structure.

2. Description of the Related Art

Generally, an electronic device includes multiple electronic components, such as a motherboard, a hard disk drive or an optical disk drive. The electronic components are directly fixed at a casing of the electronic device via screws. However, when the casing is hit, the electronic components may be damaged.

Furthermore, some electronic components (such as a hard disk drive or an optical disk drive) would generate vibration in operation, the vibration travels to the casing of the electronic device and noise is generated. In order to solve the problem of noise due to the vibration, anti-vibration rubber materials are disposed around the electronic components to absorb the vibration in operation. However, the method increases the manufacture cost and makes the assembly complicated.

### BRIEF SUMMARY OF THE INVENTION

An electronic device includes an electronic component which would generate vibration in operation, a fixing plate, an anti-vibration fixing structure and a locking element. The fixing plate fixes the electronic component. The anti-vibration fixing structure is disposed at the fixing plate, and the anti-vibration fixing structure includes a connecting portion and a buffer. The connecting portion includes a hole. The buffer is connected to the connecting portion and the fixing plate. The locking element passes through the hole to lock the electronic component on the fixing plate.

An anti-vibration fixing structure disposed at a fixing plate of an electronic device is used to fix an electronic component which would generate vibration in operation. The anti-vibration fixing structure includes a connecting portion and a buffer, and the connecting portion includes a hole. The buffer is connected to the connecting portion and the fixing plate.

As stated above, the electronic device can absorb and reduce the vibration via the anti-vibration fixing structure at the fixing plate. A plurality of the buffers is disposed at the anti-vibration fixing structure, and the buffers do not contact with each other. When the electronic component generates vibration in operation, the buffers can absorb the vibration and reduce the effect of the vibration on the fixing plate, so as to achieve an anti-vibration effect. On the contrary, when the fixing plate is hit to generate vibration, the effect of the vibration on the electronic component can be reduced via the buffer.

These and other features, aspects and advantages of the present disclosure will become better understood with regard to the following description, appended claims, and accompanying drawings.

### BRIEF DESCRIPTION OF THE DRAWINGS

FIG. 1 is a schematic diagram showing an electronic device in an embodiment;

FIG. 2 is an enlarged view showing the A area of the electronic device in FIG.

FIG. 3 is an enlarged view showing an anti-vibration fixing structure in FIG. 2:

FIG. 4A is a sectional diagram showing the electronic device in FIG. 2 along a B-B line;

FIG. 4B is a schematic diagram showing a connection of a connecting portion and a buffer in FIG. 4A in another embodiment; and

FIG. 5 to FIG. 7 are schematic diagrams showing an anti-vibration fixing structure in other embodiments.

### DETAILED DESCRIPTION OF THE EMBODIMENTS

An electronic device and an anti-vibration fixing structure are illustrated with relating figures, and the same symbols denote the same components.

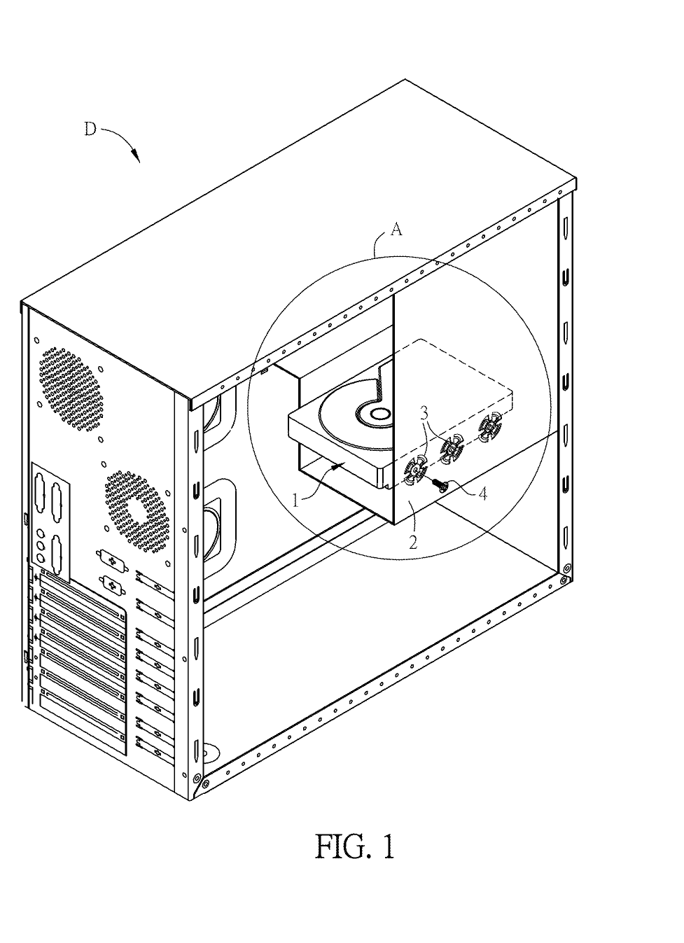

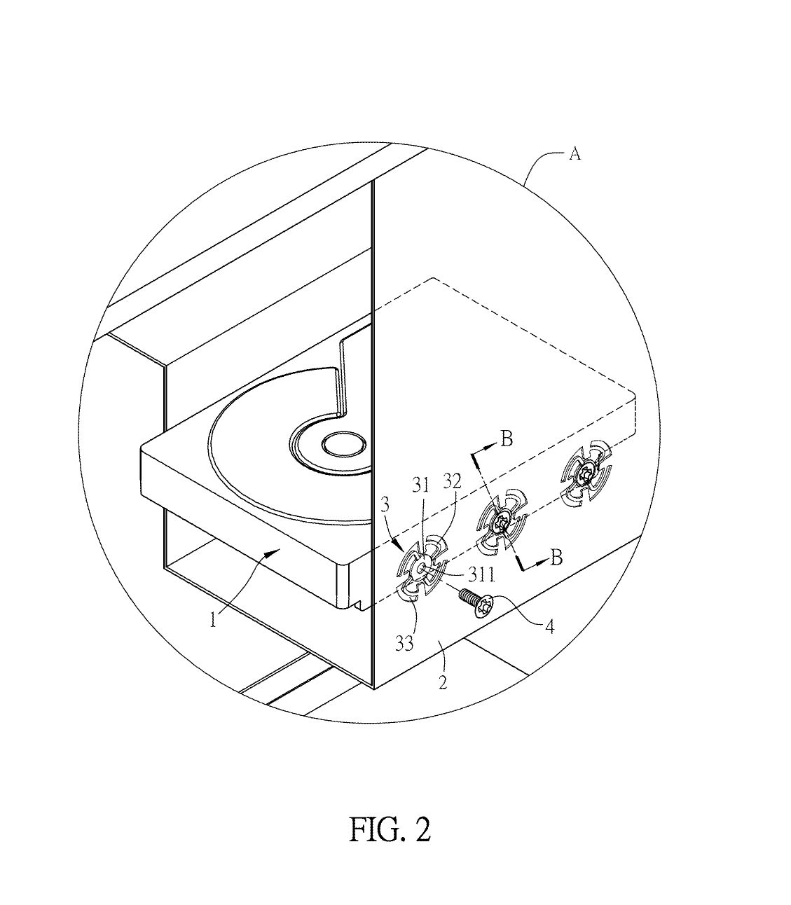

FIG. 1 is a schematic diagram showing an electronic device in an embodiment, and FIG. 2 is an enlarged view showing the A area of the electronic device in FIG. 1. Please refer to FIG. 1 and FIG. 2, the electronic device D in the embodiment includes an electronic component 1 which would generate vibration in operation, a fixing plate 2, at least one anti-vibration fixing structure 3 and a locking element 4.

In the embodiment, the electronic device D is a host of a desktop computer, and the electronic component 1 is a hard disk drive as an example. In other embodiments, the electronic device D may also be a notebook computer, a video player or a projector which includes the electronic component 1. The electronic component 1 may also be an optical disk drive, a power supply or a host fan, which is not limited herein. The fixing plate 2 can be a plate inside the electronic device D for fixing the electronic component 1 or a casing of the electronic device D, which is not limited herein.

As shown in FIG. 2, the fixing plate 2 fixes the electronic component 1, and the anti-vibration fixing structures 3 are disposed at the fixing plate 2. The electronic component 1 is disposed at the fixing plate 2 via the anti-vibration fixing structures 3, and the number of the anti-vibration fixing structures 3 is determined as long as the electronic component 1 can be supported and fixed. It is better for the electronic device D to include two or more anti-vibration fixing structures 3.

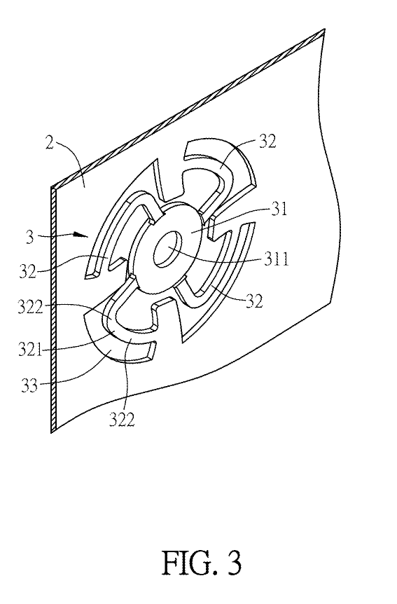

FIG. 3 is an enlarged view showing the anti-vibration fixing structure in FIG. 2. The anti-vibration fixing structure 3 includes a connecting portion 31 and multiple buffers 32. The buffers 32 are connected to the connecting portion 31 and the fixing plate 2, and the buffers 32 do not contact with each other. In the embodiment, there are four buffers 32, and in other embodiments, there can also be one buffer 32. It is better for the anti-vibration fixing structures 3 to include two or more buffers 32 for the consideration of stability, and the number of the buffers 32 is not limited.

The buffers 32 are disposed at a periphery of the connecting portion 31 at adequate intervals, and two adjacent buffers 32 form a hollow portion 33 to make the buffers 32 not contact with each other. In the embodiment, the anti-vibration fixing structure 3 is directly disposed at the fixing plate 2. In detail, the anti-vibration fixing structure 3 can be formed at the fixing plate 2 by stamping, punching, drilling or laser cutting, which is not limited herein, and then the hollow portion 33 is formed, and the connecting portion 31 and the buffers 32 are kept to form the anti-vibration fixing structure 3.

As shown in FIG. 2 and FIG. 3, the connecting portion 31 has a hole 311, and the locking element 4 passes through the hole 311 to lock the electronic component 1 to the fixing plate 2. In the embodiment, the locking element 4 is a screw as an example. Furthermore, the electronic component 1 also has corresponding locking holes (not shown) for the locking element 4 to pass through.

The locking element 4 may also be a rivet, a hook or a locker. The type of the locking element 4 is not limited as long as it can pass through the hole 311 to lock the electronic component 1, and both the connecting portion 31 and the electronic component 1 include a structure corresponding to the locking element 4, which is not limited herein.

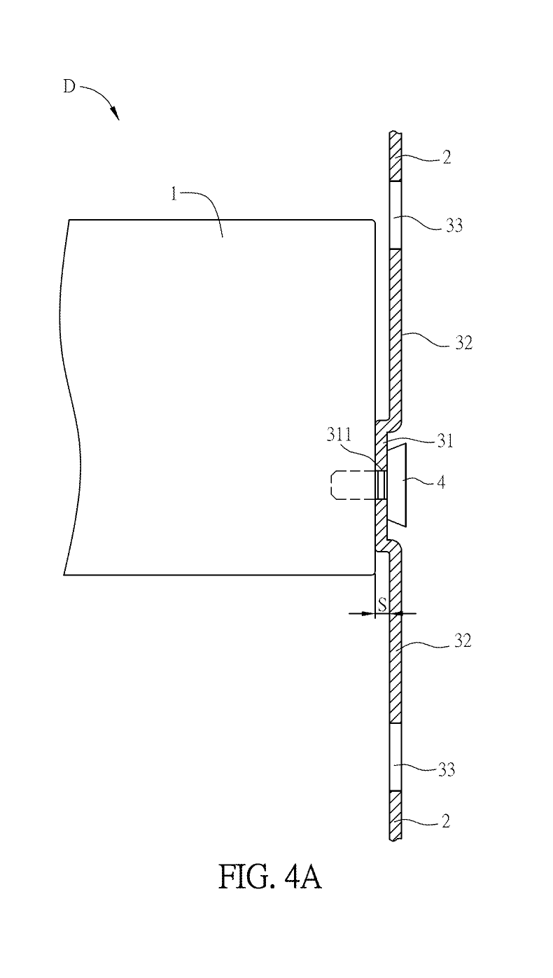

FIG. 4A is a sectional diagram showing the electronic device in FIG. 2 along a BB line. The fixing plate 2 is a base plane. The buffers 32 are coplanar with the fixing plate 2, and a level difference S exists between the connecting portion 31 and the buffers 32. Thus, the connecting portion 31 is not coplanar with the fixing plate 2.

The connecting portion 31 concaves towards the electronic component 1, so that the buffers 32 do not contact with the electronic component 1. Furthermore, as shown in FIG. 4A, the connection between the connecting portion 31 and the buffers 32 forms a 90° angle. FIG. 4B is a schematic diagram showing a connection of the connecting portion and the buffers in FIG. 4A in another embodiment. The connection between the connecting portion 31 a and the buffers 32a may also form an angle larger than 90° (or smaller than 90°, which is not shown) so as to make the buffers 32a not contact with the electronic component 1, which is not limited herein.

Since the electronic component 1 only contacts with the connecting portion 31 and does not contact with other structures, when the electronic component 1 generates vibration in operation, the vibration passes through the connecting portion 31, and travels to the buffers 32 and the fixing plate 2 in sequence, which can enhance the anti-vibration effect. Contrarily, when the fixing plate 2 is greatly hit, the vibration generated due to the hitting passes through the buffers 32, and then travels to the connecting portion 31 and the locking element 4. Since the buffers 32 do not contact with the electronic component 1, it can avoid that the locking element 4 and the connecting portion 31 deform due to the hitting, and the vibration caused by the hitting is absorbed to reduce the effect of the vibration on the electronic component 1.

Moreover, the anti-vibration fixing structure 3 is not limited. The buffer 32 includes at least one straight portion, at least one arc portion, at least one bending portion, at least one block or a combination. For example, as shown in FIG. 3, the buffer 32 is L-shaped, which means that the buffer 32 has a bending portion 321 approximate to a right angle, and two ends of the bending portion 321 are connected to arc portions 322.

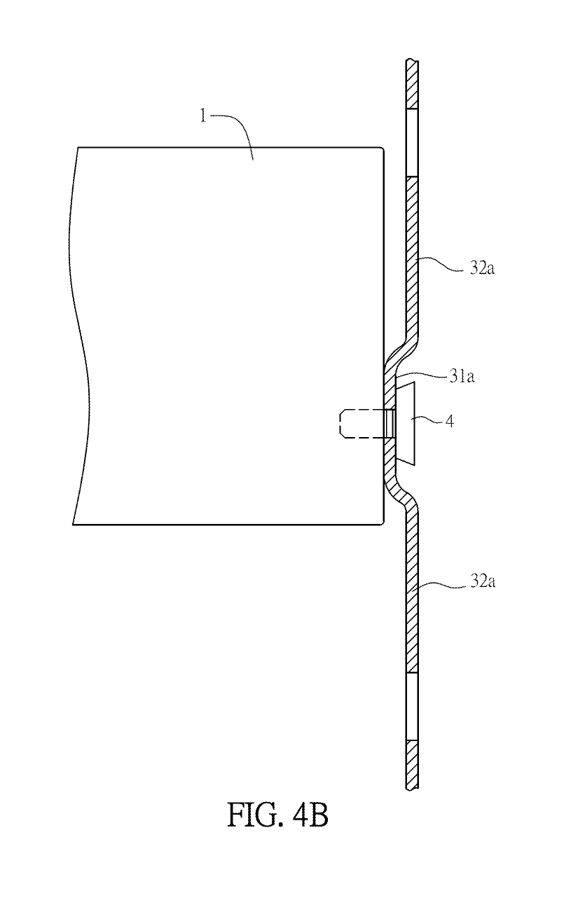

FIG. 5 to FIG. 7 are schematic diagrams showing an anti-vibration fixing structure in other embodiments. As shown in FIG. 5, the buffer 32b of the anti-vibration fixing structure 3b includes a plurality of bending portions 321b, and the straight portion 323b is connected to the arc portion 322b.

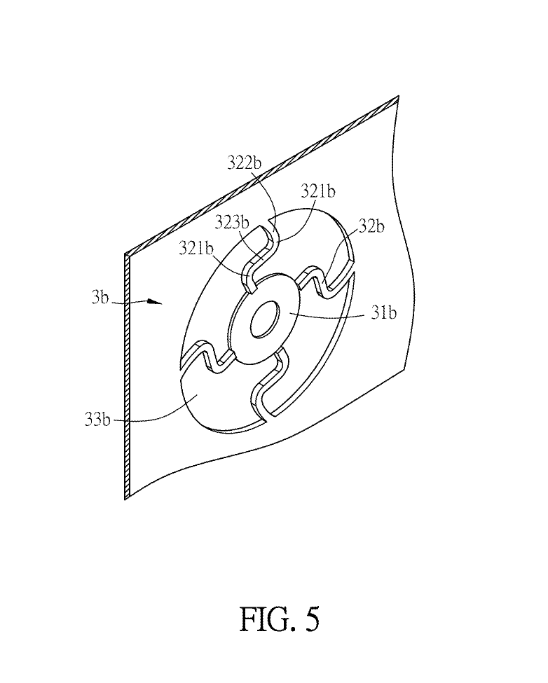

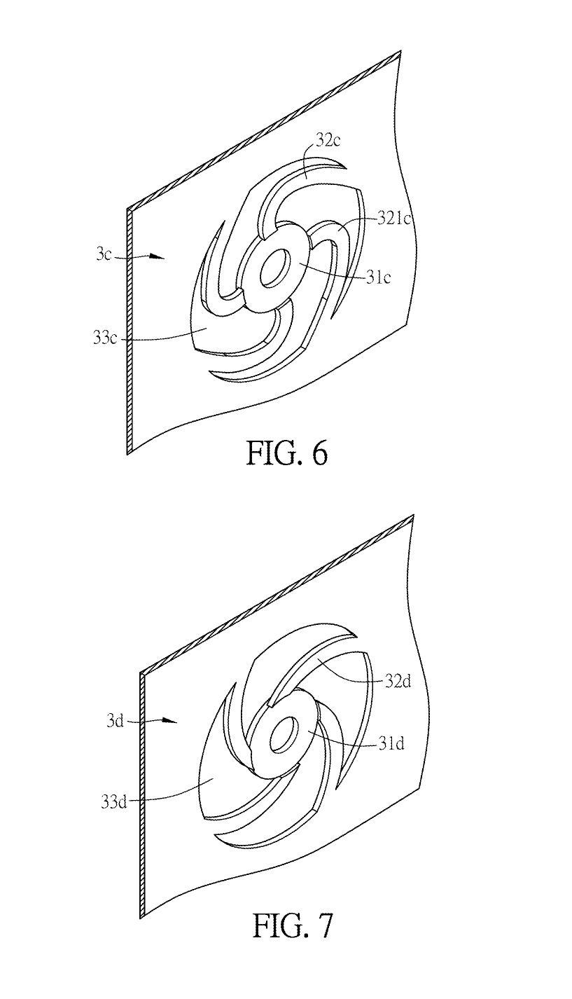

Furthermore, as shown in FIG. 6, the angle of the bending portion 321c may be large, which is not limited herein. As shown in FIG. 7, the buffer 32d of the anti-vibration fixing structure 3d may also be a line-shaped structure. Only while the hollow portion 33d is formed between two adjacent buffers 32d, a buffer and anti-vibration effect can be achieved, and the shape of the buffers 32d or the hollow portion 33d is not limited.

Although the present disclosure has been described in considerable detail with reference to certain preferred embodiments thereof, the disclosure is not for limiting the scope. Persons having ordinary skill in the art may make various modifications and changes without departing from the scope. Therefore, the scope of the appended claims should not be limited to the description of the preferred embodiments described above.

What is claimed is:

1. An electronic device, comprising:
an electronic component;
a fixing plate; and
an anti-vibration fixing structure disposed at the fixing plate, wherein the anti-vibration fixing structure includes:
a connecting portion including a hole; and
at least one buffer connected to the connecting portion and the fixing plate,
wherein the electronic component is locked to the fixing plate via a locking element passing through the hole.

2. The electronic device according to claim 1, wherein when a plurality of the buffers are disposed at the anti-vibration fixing structure, the buffers are disposed at a periphery of the connecting portion, respectively.

3. The electronic device according to claim 2, wherein a hollow portion is formed between the two adjacent buffers.

4. The electronic device according to claim 1, wherein a level difference exists between the buffer and the connecting portion.

5. The electronic device according to claim 1, wherein the buffer includes one or a combination of at least one straight portion, at least one arc portion, at least one bending portion and at least one block.

6. An anti-vibration fixing structure disposed at a fixing plate of an electronic device for fixing an electronic component, wherein the anti-vibration fixing structure includes:
a connecting portion including a hole; and
at least one buffer connected to the connecting portion and the fixing plate.

7. The anti-vibration fixing structure according to claim 6, wherein when a plurality of the buffers are disposed at the anti-vibration fixing structure, the buffers are disposed at a periphery of the connecting portion, respectively.

8. The anti-vibration fixing structure according to claim 7, wherein a hollow portion is formed between the two adjacent buffers.

9. The anti-vibration fixing structure according to claim 6, wherein a level difference exists between the buffer and the connecting portion.

10. The anti-vibration fixing structure according to claim 6, wherein the buffer includes one or a combination of at least one straight portion, at least one arc portion, at least one bending portion and at least one block.
